(19) United States
(12) Patent Application Publication
(10) Pub. No.: US 2013/0119342 A1
(43) Pub. Date: May 16, 2013

(54) METHOD FOR MANUFACTURING SEMICONDUCTOR MEMORY DEVICE AND SEMICONDUCTOR MEMORY DEVICE

(71) Applicants: Takeshi YAMAGUCHI, Mie-ken (JP); Hiroyuki FUKUMIZU, Kanagawa-ken (JP)

(72) Inventors: Takeshi YAMAGUCHI, Mie-ken (JP); Hiroyuki FUKUMIZU, Kanagawa-ken (JP)

(21) Appl. No.: 13/676,363

(22) Filed: Nov. 14, 2012

(30) Foreign Application Priority Data
Nov. 15, 2011 (JP) 2011-249399

(51) Int. Cl. H01L 45/00

(52) U.S. Cl. CPC H01L 45/00; H01L 28/20
USPC 257/4; 438/382

(57) ABSTRACT

According to one embodiment, a method is disclosed for manufacturing a semiconductor memory device. The method can include introducing halogen in a contact layer with a resistance variation film including a metal oxide. The method can include diffusing the halogen from the contact layer to the resistance variation film by a thermal treatment.

### CROSS-REFERENCE TO RELATED APPLICATION

This application is based upon and claims the benefit of priority from Japanese Patent Application No. 2011-249399, filed on Nov. 15, 2011; the entire contents of which are incorporated herein by reference.

### FIELD

Embodiments described herein relate generally to a method for manufacturing a semiconductor memory device and a semiconductor memory device.

### BACKGROUND

As a new non-volatile semiconductor memory device, a structure in which word lines, bit lines, and resistance variation films interposed between the word lines and the bit lines, which serve as recording layers are stacked is suggested. By controlling an amount of a voltage which is applied to the resistance variation film and the application time, the resistance variation film may be switched so as to be in at least two resistance states having relatively different resistances. A metal oxide film is suggested as such a resistance variation film.

### BRIEF DESCRIPTION OF THE DRAWINGS

FIG. 1 is a schematic perspective view of a memory cell array of a semiconductor memory device of an embodiment;

FIG. 2 is a schematic sectional view of the semiconductor memory device of the embodiment;

FIG. 3A to FIG. 5B are schematic sectional views showing a method for manufacturing a semiconductor memory device of a first embodiment;

FIG. 6A is a schematic sectional view showing a method for manufacturing a semiconductor memory device of a second embodiment, FIG. 6B is a schematic sectional view showing a method for manufacturing a semiconductor memory device of a third embodiment;

FIG. 7 is a schematic view showing a method for manufacturing a semiconductor memory device of a fifth embodiment;

FIGS. 8A and 8B show dependence of a time for resistance change of an aluminum oxide film on fluorine concentration; and

FIG. 9 shows dependence of a voltage on fluorine concentration at a time when the resistance of the aluminum oxide film is decreased.

### DETAILED DESCRIPTION

According to one embodiment, a method is disclosed for manufacturing a semiconductor memory device. The method can include introducing halogen in a contact layer with a resistance variation film including a metal oxide. The method can include diffusing the halogen from the contact layer to the resistance variation film by a thermal treatment.

Various embodiments will be described hereinafter with reference to the accompanying drawings. In the drawings, like components are denoted by like reference numerals.

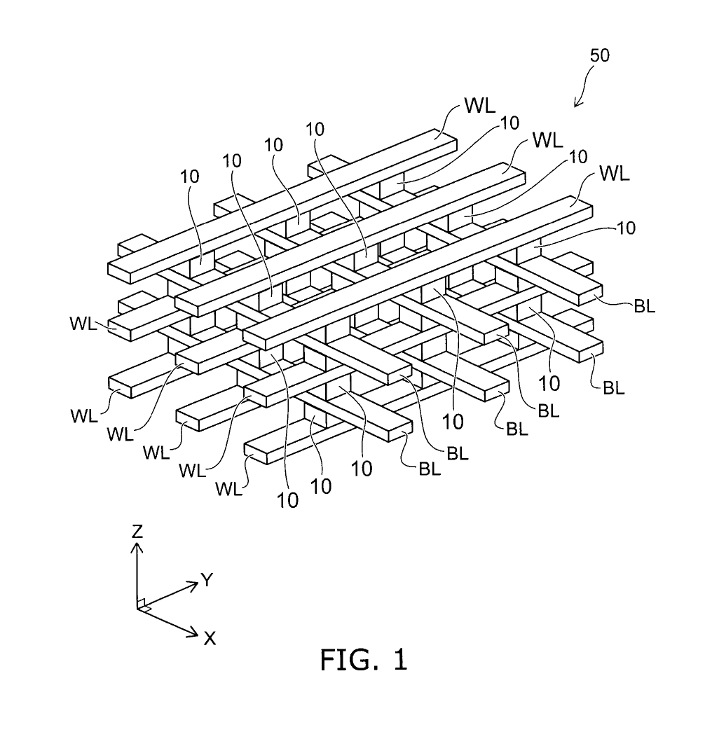

FIG. 1 is a schematic perspective view of a part of a memory cell array 50 in a semiconductor memory device according to an embodiment.

The memory cell array 50 includes a plurality of word lines WL and a plurality of bit lines BL. Further, the memory cell array 50 includes a plurality of pillar shaped stacked bodies 10 interposed between the word lines WL and the bit lines BL.

The word lines WL and the bit lines BL are not parallel to each other in a plan view and three-dimensionally cross with each other. The stacked bodies 10 are provided at the cross point where the word lines WL and the bit lines BL cross with each other.

The plurality of stacked bodies 10 are arranged in a two-dimensional direction (XY direction), for example, in a matrix, and a plurality of matrix-shaped arrays are stacked in a Z direction which is perpendicular to the XY plane. FIG. 1 shows a portion in which four arrays of, for example, 3 columns×3 rows are stacked.

Each of the word lines WL is shared between the upper and lower stacked bodies 10. Similarly, each of the bit lines BL is shared between the upper and lower stacked bodies 10.

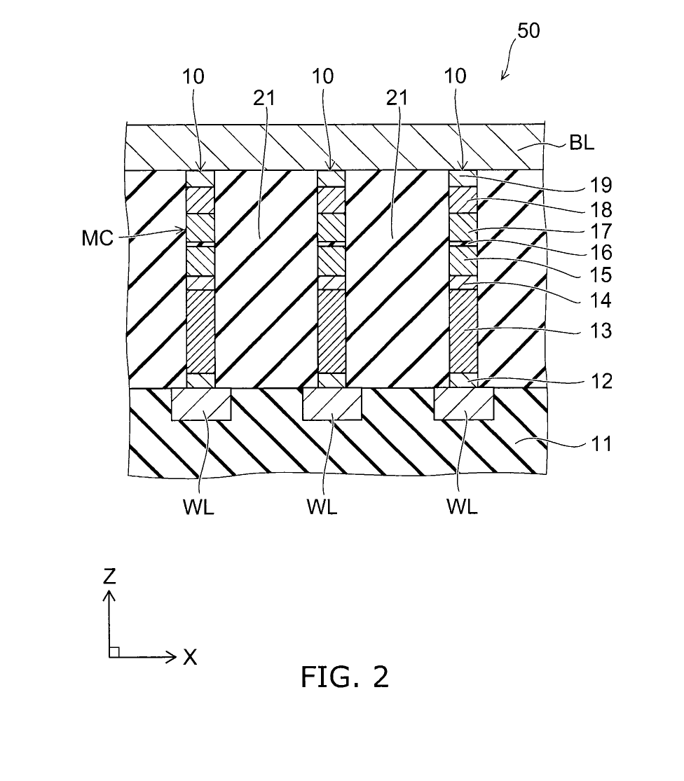

In FIG. 2, a cross-sectional structure of the stacked body 10 is shown. FIG. 2 corresponds to an XZ cross-section of an array in FIG. 1.

The stacked body 10 includes a memory cell MC and a diode 13 which are serially connected between the bit lines BL and the word lines WL.

The memory cell MC includes an upper electrode 18, a lower electrode 15, and a resistance variation film 17 provided between the upper electrode 18 and the lower electrode 15.

The diode 13 is a silicon diode having a p-intrinsic-n (PIN) structure, for example. The diode 13 may be omitted.

The resistance variation film 17 may electrically switch a state having a relatively low resistance (set condition) and a state having a relatively high resistance (reset condition), and non-volatilely stores data. The diode 13 prevents a sneak current from occurring when the diode 13 electrically accesses to a selective cell (forming/writing/deleting/reading).

The resistance variation film 17 includes a metal oxide. As the metal oxide, for example, an oxide including one element or two or more elements selected from a group consisting of zirconium (Zr), titanium (Ti), aluminum (AL), hafnium (Hf), manganese (Mn), tantalum (Ta), tungsten (W), niobium (Nb), silicon (Si) and germanium (Ge) may be used. The resistance variation film 17 contains halogen in addition to the metal oxide.

The lower electrode 15 is, for example, a conductive polycrystalline silicon film to which impurities are added. On a surface of the lower electrode 15, a silicon oxide film 16 which is a natural oxide film is formed according to the process. Therefore, the silicon oxide film 16 is interposed between the lower electrode 15 and the resistance variation film 17. However, the silicon oxide film 16 is significantly thin, which may not prevent a current from being conducted between the lower electrode 15 and the resistance variation film 17.

As the upper electrode 18, a metal film or a metal nitride film may be used. As the upper electrode 18, for example, a titanium nitride film may be used.

The bit lines BL and the word lines WL are metal interconnects, for example. As materials of the bit lines BL and the word lines WL, for example, tungsten, titanium, tantalum, or a nitride of the above metals may be used.

Between the word lines WL and the diode 13, a barrier metal 12 is provided. The barrier metal 12 prevents the diffusion of elements between the word lines WL and the diode 13. Further, the barrier metal 12 increases the adhesiveness between the word lines WL and the diode 13. As the barrier metal 12, a metal film or a metal nitride film may be used, and, for example, a titanium nitride film may be used.

Between the diode 13 and the lower electrode 15, a barrier metal 14 is provided. The barrier metal 14 prevents the diffusion of elements between the diode 13 and the lower electrode 15. Further, the barrier metal 14 increases the adhesiveness between the diode 13 and the lower electrode 15.

As the barrier metal 14, a metal film or a metal nitride film may be used, and, for example, a titanium nitride film may be used.

Between the upper electrode 18 and the bit lines BL, a contact metal 19 is provided. As the contact metal 19, a metal film or a metal nitride film may be used, and, for example, a titanium nitride film may be used.

The above-mentioned stacked bodies 10 including the memory cell MC and the diode 13 are processed to have a pillar shape and an interlayer insulating film 21 is provided between adjacent stacked bodies 10. As the interlayer insulating film 21, for example, a silicon oxide film or a silicon nitride film may be used.

If a reset voltage is applied to the resistance variation film 17 which is in a low resistance state (set condition) having a relatively low resistance through the word lines WL and the bit lines BL, the resistance variation film 17 may be switched to be in a high resistance state (reset condition) having a relatively high resistance. If a set voltage which is higher than the reset voltage is applied to the resistance variation film 17 in a high resistance state (reset condition), the resistance variation film 17 may be switched to be in a low resistance state (set condition).

It is considered that the movement of oxygen (including an oxygen ion) in the metal oxide contributes to the resistance variation of the resistance variation film 17 including the metal oxide. Introduction of oxygen vacancy (oxygen depletion) is effective for the improvement of the mobility of the oxygen.

According to the embodiment, halogen is introduced into the resistance variation film 17. If the halogen is introduced into the metal oxide, halogen is substituted with oxygen, and the oxygen vacancy is promoted to be induced in the metal oxide. By doing this, the oxygen vacancy in the resistance variation film 17 is increased and oxygen is easily moved by an electric field which is applied to the resistance variation film 17. Specifically, the mobility of the oxygen is improved. As a result, it is possible to lower an operating voltage and an operating current.

If fluorine which has highest electronegativity in halogen is used, it is possible to most efficiently decouple oxygen and a metal in the metal oxide so that more oxygen vacancies are easily induced.

For example, if a concentration of fluorine in a hafnium oxide film as the resistance variation film 17 is 1×10¹⁵ cm⁻² or more, it is possible to verify that the operating voltage and the operating current are remarkably lowered.

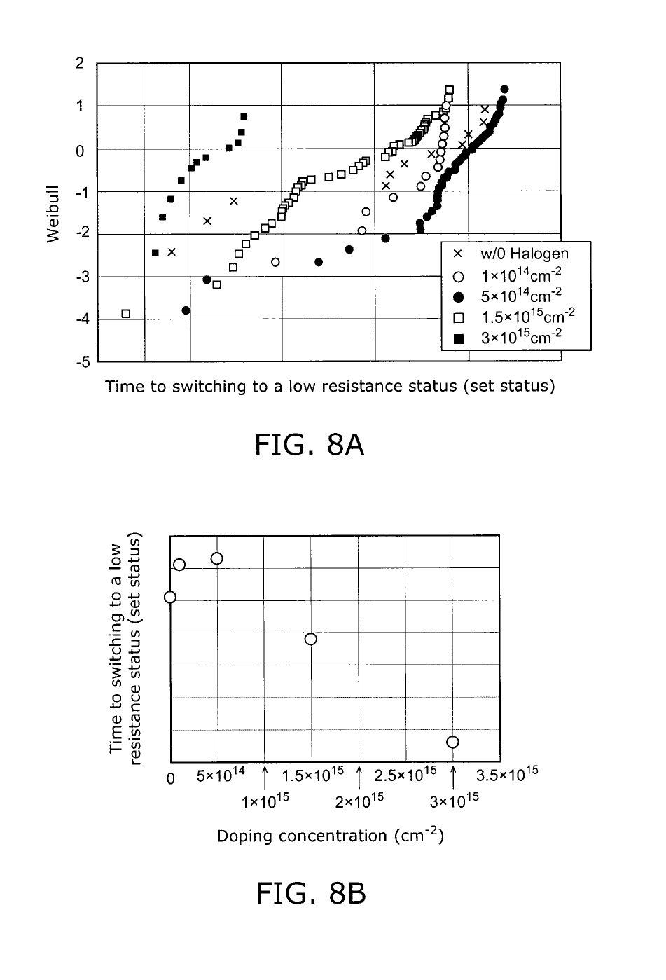

FIG. 8A shows a Weibull plot of time needed for the resistance of the aluminum oxide film to be decreased at a constant voltage. White circles represent data for the aluminum oxide film with a fluorine concentration of 1×101⁴ cm⁻². Black circles represent data for the aluminum oxide film with a fluorine concentration of 5×10¹⁴ cm⁻². White squares represent data for the aluminum oxide film with a fluorine concentration of 1×10¹⁵ cm⁻². Black squares represent data for the aluminum oxide film with a fluorine concentration of 3×10¹⁵ cm⁻². Crosses represent data for the aluminum oxide film without fluorine.

FIG. 8B is a graph showing plotted median of FIG. 8A.

In FIGS. 8A and 8B, it is seen that when the fluorine concentration if the aluminum oxide film is not less than 1×10¹⁵ cm⁻², the switching time is remarkably lowered.

Also if a fluorine concentration in a hafnium oxide film as the resistance variation film 17 is 1×10¹⁵ cm⁻² or more, it is possible to verify that the operating voltage and the operating current are remarkably lowered similar to the aluminum oxide film.

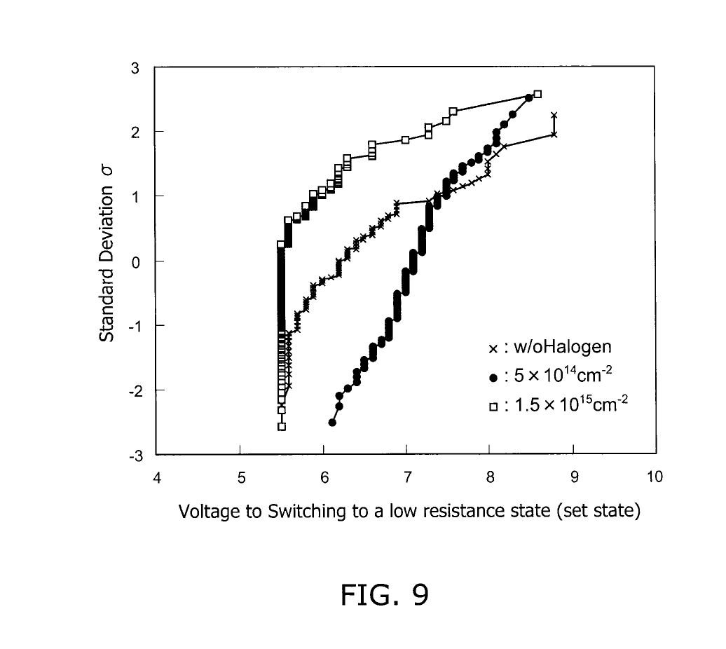

FIG. 9 shows a standard deviation a of a voltage at a time when an applied voltage to the hafnium oxide film is increased and the resistance of the aluminum oxide film is decreased.

Black circles represent data for the hafnium oxide film with a fluorine concentration of 5×10¹⁴ cm⁻². White circles represent data for the hafnium oxide film with a fluorine concentration of 1.5×10¹⁴ cm⁻². Crosses represent data for the hafnium oxide film without fluorine.

In FIG. 9, it is seen that when the fluorine concentration if the hafnium oxide film is not less than 1×10¹⁵ cm⁻², the switching time is remarkably lowered.

Further, according to the embodiment, the lower electrode 15 is formed of a silicon film. In the silicon film, it is difficult to accumulate electrons as compared with the metal film. Therefore, at the time of a forming operation that forms a leakage pass in the resistance variation film 17 or a set operation performed to make a high resistance state, even though the resistance value of the resistance variation film 17 is suddenly lowered, it is possible to prevent the overcurrent from flowing into the resistance variation film 17. Accordingly, it is possible to prevent the damage of the resistance variation film 17 and thus provide a high reliable semiconductor memory device.

In addition, the silicon oxide film 16 formed on the surface of the silicon film is present at an interface with the resistance variation film 17. The silicon oxide film 16 is considered to contribute to easily changing the resistance of the resistance variation film 17.

Furthermore, when instead of the lower electrode 15, the upper electrode 16 is formed of the silicon film, the same effect may be obtained.

Next, a method for manufacturing a memory cell array 50 according to the embodiment will be described.

### First Embodiment

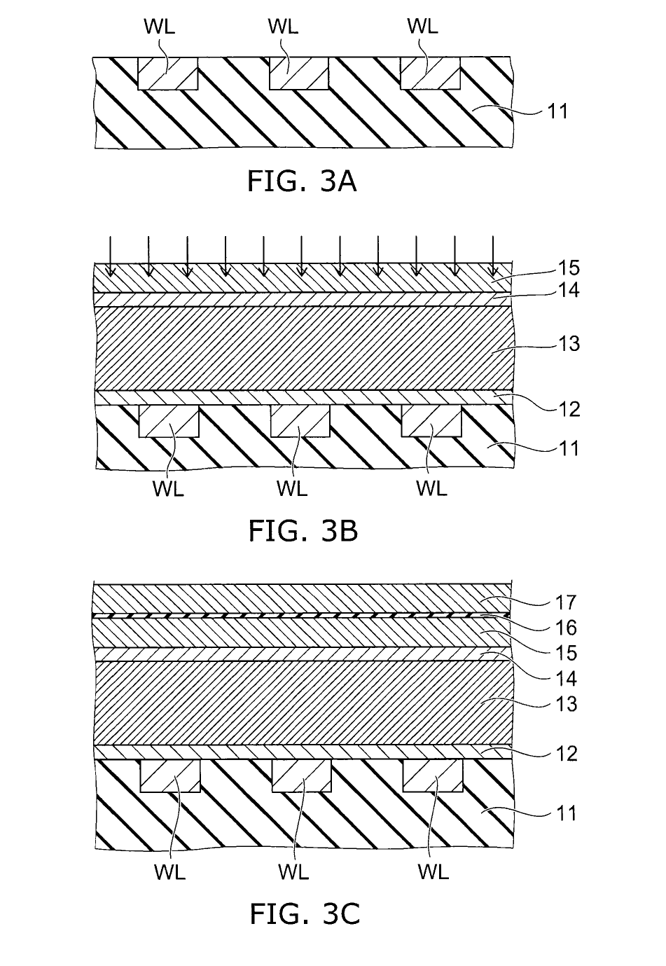

FIG. 3A to FIG. 5B show a first embodiment of the method for manufacturing the memory cell array 50.

As shown in FIG. 3A, for example, in a wiring groove formed in an interlayer insulating film 11 such as a silicon oxide film or a silicon nitride film, word lines WL are provided. The word lines WL, for example, may be formed by a damascene method. Top surfaces of the word lines WL are exposed from the interlayer insulating film 11.

FIG. 3A to FIG. 5B correspond to the same cross-sectional direction as FIG. 2 and the word lines WL extend in a direction penetrating the sheet.

On the interlayer insulating film 11, as shown in FIG. 3B, a barrier metal 12, a diode 13, and a barrier metal 14 are formed in this order.

On the barrier metal 14, a lower electrode 15 is formed. For example, a polycrystalline silicon film is formed by a chemical vapor deposition (CVD) method as the lower electrode 15.

After forming the lower electrode 15, as schematically shown by arrows in FIG. 3B, for example, fluorine as halogen is introduced into the lower electrode 15 using an ion implantation method. For example, an ion such as F₂⁺ or BF₂⁺ is implanted with a surface concentration of 2×10¹⁵ cm⁻².

After the ion implantation, on the lower electrode 15, as shown in FIG. 3C, a resistance variation film 17 is formed. According to the process, a silicon oxide film 16 is formed on the surface of the lower electrode 15 which is a silicon film and the resistance variation film 17 is formed on the lower electrode 15 with the silicon oxide film 16 formed between the resistance variation film 17 and the lower electrode 15. The resistance variation film 17 is formed by, for example, an atomic layer deposition (ALD) method.

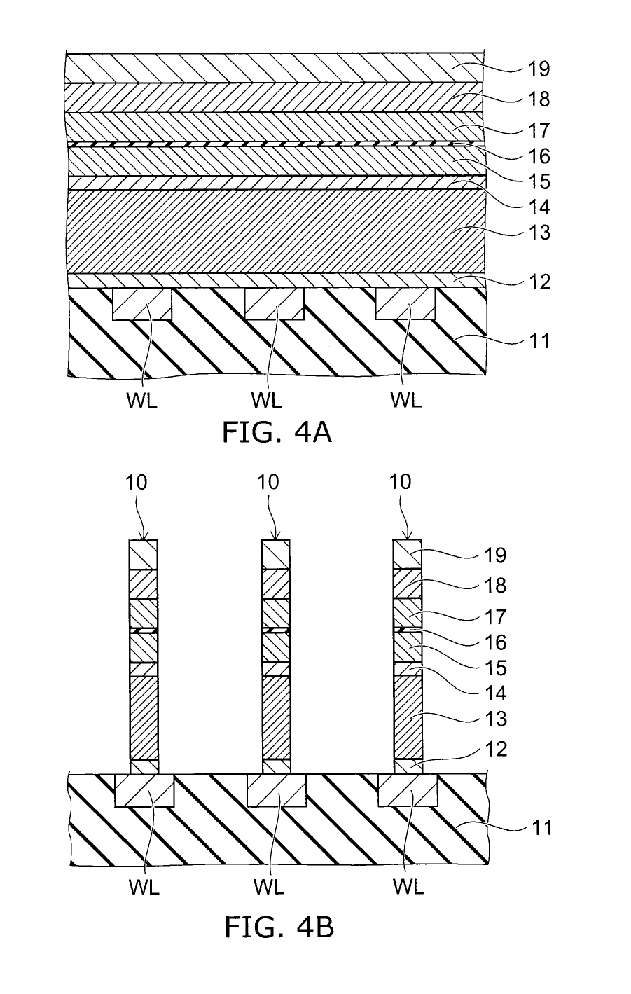

On the resistance variation film 17, as shown in FIG. 4A, an upper electrode 18 is formed. For example, by reactive sputtering that sputters a titanium target under a reactive gas atmosphere including nitrogen, the titanium nitride film is formed as the resistance variation film 17.

On the upper electrode 18, a contact metal 19 is formed. Thereafter, the above-mentioned stacked body is processed so as to have a pillar shape as shown in FIG. 4B, for example by reactive ion etching (RIE) that uses a mask which is not shown. The filler-shaped stacked bodies 10 are provided on the word lines WL.

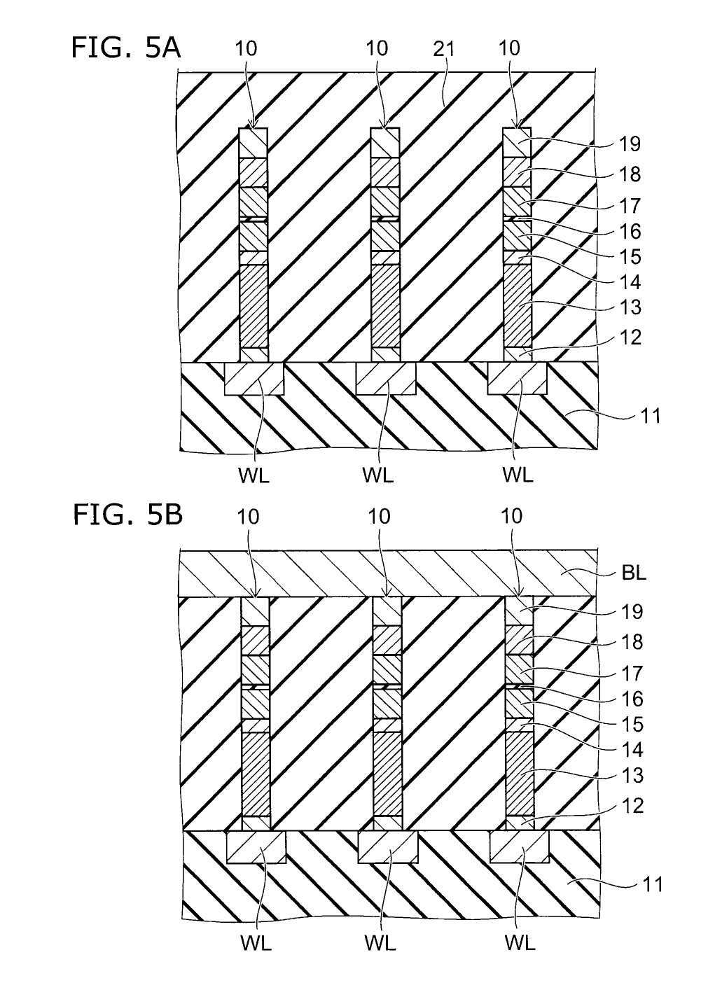

After processing the stacked bodies 10, as illustrated in FIG. 5A, an interlayer insulating film 21 is stacked on the interlayer insulating layer 12 so as to be buried between the stacked bodies 10. As the interlayer insulating film 21, for example, a silicon oxide film or a silicon nitride film is formed by the CVD method.

The top surface of the interlayer insulating film 21 is planarized by a chemical mechanical polishing (CMP) method, for example. Thereafter, for example, by the damascene method, bit lines BL shown in FIG. 5B are formed in the wiring groove formed in the interlayer insulating film 21.

The bit lines BL are in contact with the contact metal 19 and extend in a direction crossing with the word lines WL. In FIG. 5B, the bit lines BL extend in a direction which is perpendicular to the word lines WL (a horizontal direction in FIG. 5B).

By repeating the above processes, a plurality of arrays in which the stacked bodies 10 are interposed between the word lines WL and the bit lines BL are stacked to form the memory cell array 50 shown in FIG. 1.

After forming the memory cell array 50, for example, a thermal treatment at 700° C. is performed under the nitrogen atmosphere for about one minute. By doing this, the diode 13 having a PIN structure of silicon is activated. Further, by the thermal treatment, halogen (fluorine) which is ion-implanted into the lower electrode 15 is diffused into the resistance variation film 17. In the same thermal treatment process, by diffusing halogen from the lower electrode 15 into the resistance variation film 17 and activating the diode 13, it is possible to suppress an increase in the number of processes.

By the above-mentioned thermal treatment, halogen is introduced into the resistance variation film 17 and the oxygen vacancy is induced as described above. By doing this, the mobility of the oxygen in the resistance variation film 17 is improved.

According to the first embodiment, halogen is ion-implanted in the lower electrode 15 which is a contact layer with the resistance variation film 17.

In the specification, the contact layer with the resistance variation film 17 includes a layer that is not in contact with the resistance variation film 17 since the resistance variation film 17 is not formed yet when halogen is ion-implanted, but is in contact with the resistance variation film 17 if the resistance variation film 17 is formed.

Even though the silicon oxide film 16 is interposed between the lower electrode 15 and the resistance variation film 17, the silicon oxide film 16 is a natural oxide film and significantly thin. Therefore, the silicon oxide film 16 does not interrupt the movement of the halogen from the lower electrode 15 to the resistance variation film 17. Further, the silicon oxide film 16 does not interrupt the current conduction between the lower electrode 15 and the resistance variation film 17. Therefore, the lower electrode 15 is considered to be substantially in contact with the resistance variation film 17, and the lower electrode 15 is treated as the contact layer with the resistance variation film 17.

Specifically, according to the first embodiment, since halogen is not directly ion-implanted into the resistance variation film 17, it is possible to introduce halogen into the resistance variation film 17 without causing damage in the resistance variation film 17. As a result, it is possible to stabilize the characteristics of the resistance variation film 17 that mainly dominates the characteristics in a memory device and provide a high reliable semiconductor memory device.

Further, since the lower electrode 15 is a silicon film, it is possible to easily diffuse halogen from the lower electrode 15 to the resistance variation film 17. Furthermore, an ion implantation condition and a thermal treatment condition for diffusion may be easily set.

As another method that induces an oxygen vacancy into the resistance variation film (first comparative example), a method that stacks a metal film such as aluminum or titanium which is easily oxidized on the resistance variation film and extracts oxygen from the resistance variation film by the thermal treatment is considered.

However, in this case, there is a problem of mutual diffusion of metals between the resistance variation film and the metal film and thus development of a process for suppressing the metal diffusion is required. Further, since a metal film for extracting oxygen is separately formed, the height of the stacked bodies is increased and the process becomes complicated.

In contrast, according to the embodiment, halogen is ion-implanted into the lower electrode 15 of the memory cell which is originally provided and then diffused into the resistance variation film 17 by the subsequent thermal treatment. Even though the lower electrode 15 contains halogen, the function as an electrode is not affected. That is, according to the embodiment, without losing original functions of the resistance variation film 17 and the lower electrode 15, the process tolerance is not deteriorated and the difficulty level of the process is not increased.

### Second Embodiment

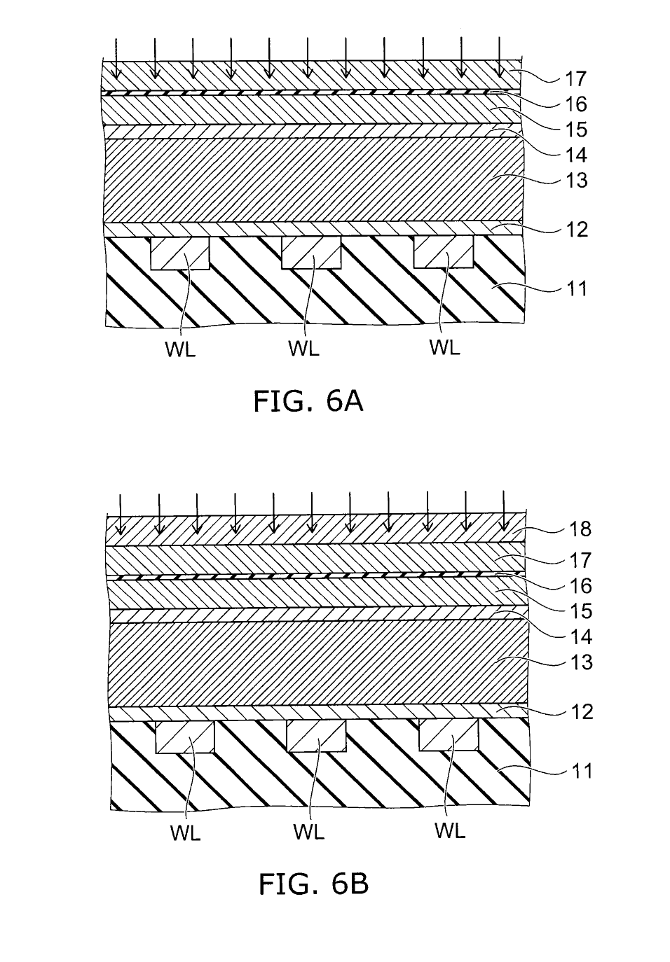

After forming the resistance variation film 17, as schematically shown by arrows in FIG. 6A, halogen may be introduced into the resistance variation film 17 by a direct ion implantation method.

For example, as a second comparative example, in a method that exposes the resistance variation film under the halogen contained gas atmosphere, it is difficult to introduce halogen into the inside of the resistance variation film.

In contrast, according to a second embodiment, by appropriately controlling an ion accelerating voltage, it is possible to certainly introduce halogen into the inside of the resistance variance film 17. Therefore, the oxygen vacancy that is induced in the resistance variation film 17 is surely ensured to sufficiently improve the oxygen mobility.

### Third Embodiment

Further, after forming the upper electrode 18, as schematically shown by arrows in FIG. 6B, halogen may be introduced into the upper electrode 18 by an ion implantation method.

The upper electrode 18 is a contact layer with the resistance variation film 17. Therefore, by the thermal treatment after ion implantation (for example, thermal treatment at the time of activating the diode 13), the halogen that is introduced into the upper electrode 18 is diffused in the resistance variation film 17 to be introduced into the resistance variation film 17.

Also, in the third embodiment, since halogen is not directly ion-implanted into the resistance variation film 17, it is possible to introduce halogen into the resistance variation film 17 without causing damage in the resistance variation film 17.

Even though the upper electrode 18 contains halogen, the function as an electrode is not affected. That is, without losing the original functions of the resistance variation film 17 and the upper electrode 18, the process tolerance is not deteriorated and the difficulty level of the process is not increased.

### Fourth Embodiment

At the time of forming the interlayer insulating film 21 shown in FIG. 5A, halogen may be contained in the interlayer insulating film 21. For example, when the interlayer insulating film 21 is formed by the CVD method, gas including halogen together with a source gas is introduced into a chamber to form the interlayer insulating film 21 containing halogen.

By processing the stacked body 10 to have a pillar shape, a side wall of the resistance variation film 17 is exposed. The interlayer insulating film 21 is a contact layer that is in contact with the side wall of the resistance variation film 17. Accordingly, by the subsequent thermal treatment (for example, thermal treatment at the time of activating the diode 13), the halogen that is contained in the interlayer insulating film 21 is diffused from the side wall of the resistance variation film 17 into the resistance variation film 17 to be introduced into the resistance variation film 17.

### Fifth Embodiment

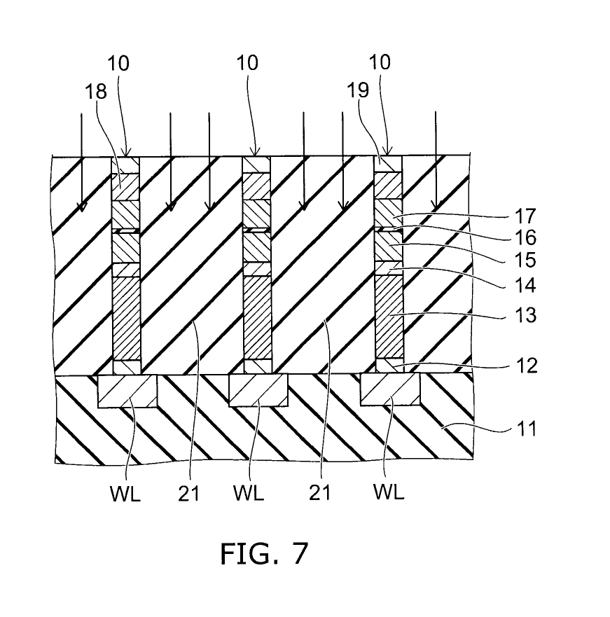

In order to allow halogen to be contained in the interlayer insulating film 21, as schematically shown by arrows in FIG. 7, halogen may be introduced into the interlayer insulating film 21 by the ion implantation method.

Also, in this case, since halogen is not directly ion-implanted into the resistance variation film 17, it is possible to introduce halogen into the resistance variation film 17 without causing damage in the resistance variation film 17.

The above-mentioned thermal treatment that diffuses halogen from the contact layer to the resistance variation film 17 may be separately performed from the thermal treatment for activating the diode 13. In this case, the thermal treatment conditions suitable for the halogen diffusion and the activation of the diode 13 may be separately set. In the thermal treatment for halogen diffusion, halogen is introduced into the contact layer. Further as long as the resistance variation film 17 is formed to be in contact with the contact layer, the thermal treatment may be formed at any timing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor memory device, comprising:
introducing halogen in a contact layer with a resistance variation film including a metal oxide; and
diffusing the halogen from the contact layer to the resistance variation film by a thermal treatment.

2. The method according to claim 1,
wherein after forming a lower electrode as the contact layer, the halogen is introduced into the lower electrode by an ion implantation method, and
after forming the resistance variation film on the lower electrode into which the halogen is introduced, the halogen is diffused from the lower electrode to the resistance variation film by the thermal treatment.

3. The method according to claim 2, wherein the lower electrode includes a silicon film.

4. The method according to claim 1,
wherein after forming an upper electrode as the contact layer on the resistance variation film, the halogen is introduced into the upper electrode by an ion implantation method, and
the halogen is diffused from the upper electrode to the resistance variation film by the thermal treatment.

5. The method according to claim 4, wherein the upper electrode includes a silicon film.

6. The method according to claim 1, further comprising:
exposing a side wall of the resistance variation film; and
forming an interlayer insulating film containing the halogen on the side wall of the resistance variation film,
the halogen being diffused from the interlayer insulating film to the resistance variation film by the thermal treatment.

7. The method according to claim 1, wherein the halogen is fluorine.

8. A method for manufacturing a semiconductor memory device, comprising:
directly introducing halogen in a resistance variation film including a metal oxide by an ion implantation method.

9. The method according to claim 8, wherein the halogen is fluorine.

10. A semiconductor memory device, including:
a lower electrode;
a resistance variation film provided on the lower electrode and including a metal oxide and halogen; and
an upper electrode provided on the resistance variation film.

11. The device according to claim 10, wherein the halogen is fluorine.

12. The device according to claim 10, wherein the lower electrode includes a silicon film.

13. The device according to claim 12, further comprising:
a silicon oxide film provided between the silicon film and the resistance variation film.

14. The device according to claim 10, wherein the upper electrode includes a silicon film.

15. The device according to claim 10, wherein the metal oxide is an oxide including one element or two or more elements selected from a group consisting of zirconium (Zr), titanium (Ti), aluminum (AL), hafnium (Hf), manganese (Mn), tantalum (Ta), tungsten (W), niobium (Nb), silicon (Si), and germanium (Ge).

16. The device according to claim 10,
wherein the resistance variation film is a hafnium oxide film, and
the hafnium oxide film contains fluorine having a concentration of 1×10¹⁵ cm⁻².

17. The device according to claim 10, wherein
the resistance variation film is an aluminum oxide film, and
the aluminum oxide film contains fluorine having a concentration of 1×10¹⁵ cm⁻².
